(19) United States
(12) Patent Application Publication
(10) Pub. No.: US 2007/0069789 A1
(43) Pub. Date: Mar. 29, 2007

(54) Flip-flop circuit

(75) Inventors: Chang-Ho Do, Kyoungki-do (KR); Jee-Eun Lee, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/529,015

(22) Filed: Sep. 27, 2006

(30) Foreign Application Priority Data
Sep. 29, 2005 (KR) 2005-0090905
Apr. 28, 2006 (KR) 2006-0038715

(51) Int. Cl. H03K 3/00

(52) U.S. Cl. 327/218

(57) ABSTRACT

A flip-flop circuit includes a first inverter for inverting a signal of a first node and transferring an inverted signal to a second node, and a second inverter for feeding back a signal of the second node and transferring a feedback signal to the first node. The second inverter includes: a first PMOS transistor and a first NMOS transistor, each gate of which receives the signal of the second node; a second PMOS transistor connected to the first PMOS transistor and having a gate receiving a first voltage, the second PMOS transistor being longer than the first PMOS transistor; and a second NMOS transistor connected to the first NMOS transistor and having a gate receiving a second voltage, the second NMOS transistor being longer than the first NMOS transistor.

### FIELD OF INVENTION

The present invention relates to a semiconductor memory device, and more particularly, to a flip-flop circuit of a semiconductor memory device.

### DESCRIPTION OF RELATED ART

As an operating speed of a semiconductor memory device increases, a large number of D flip-flop circuits are used in the semiconductor memory device. A D flip-flop circuit can detect an input signal at fast speed and can output the detected input signal at fast speed. To maintain the performance of the D flip-flop circuit depends on how its pattern or layout is formed on silicon.

FIG. 1 is a circuit diagram of a conventional D flip-flop circuit.

The conventional D flip-flop circuit includes a first transmission gate TGl, a first latch 101, a second transmission gate TG2, and a second latch 103.

The first transmission gate TGl selectively transmits a data signal D in response to a clock signal CLK. The first latch 101 selectively latches an output signal of the first transmission gate TGl, that is, a signal of a node NA. The second transmission gate TG2 selectively transmits an output signal of the first latch 101, that is, a signal of a node NB. The second latch 103 latches an output signal of the second transmission gate TG2, that is, a signal of a node NC, and outputs a signal Q.

An operation of the D flip-flop circuit will be described below with reference to FIG. 2.

FIG. 2 is a timing diagram of the D flip-flop illustrated in FIG. 1.

The data signal D has a setup time tS before an initial rising edge of the clock signal CLK, and the output signal Q has a predetermined delay time tD because of the internal circuits of the D flip-flop circuit. As the setup time tS and the delay time tD are shorter, the D flip-flop circuit is considered as having good performance.

FIG. 3 is a circuit diagram of a first inverter INV1 and a second inverter INV2 of the first and second latches 101 and 103 illustrated in FIG. 1.

The first inverter INV1 of the first latch 101 includes a PMOS transistor P1 and an NMOS transistor N1 connected between a power supply voltage VDD and a ground voltage VSS. The output signal NA is commonly inputted to the PMOS transistor P1 and the NMOS transistor N1. The second inverter INV2 of the second latch 103 has the same structure as the first inverter INV1 of the first latch 101, except that the output signal Q is commonly inputted to the PMOS transistor P1 and the NMOS transistor N1 of the second inverter INV2.

The clause “the setup time tS is short” means that the latch operates so fast that the signal of the node NA is transmitted as the signal of the node NB in a short time, or the signal of the node NC is transmitted as the output signal Q in a short time.

However, if the latch operates fast, the output signal of the transmission signal and the feedback signal of the latch may conflict with each other at the node NA, thus reducing an overall operating speed of the D flip-flop.

To solve the problem, as illustrated in FIG. 3, the PMOS transistor P1 and the NMOS transistor N1 are formed to have narrow widths W and long lengths L. However, the long lengths of the PMOS transistor P1 and the NMOS transistor N1 cause a load increase at the nodes NA and NB. This is a factor that degrades the transition performance of the nodes NA and NB.

### SUMMARY OF THE INVENTION

It is, therefore, an object of the present invention to provide a latch that can improve signal transfer characteristics.

It is another object of the present invention to provide a flip-flop circuit that can improve signal transfer characteristics.

In accordance with an aspect of the present invention, there is provided a flip-flop circuit including: a first inverter for inverting a signal of a first node and transferring an inverted signal to a second node; and a second inverter for feeding back a signal of the second node and transferring a feedback signal to the first node. In addition, the second inverter includes: a first PMOS transistor and an NMOS transistor, each gate of which receives the signal of the second node; a second PMOS transistor connected to the first PMOS transistor and having a gate receiving a first voltage, the second PMOS transistor being longer than the first PMOS transistor; and a second NMOS transistor connected to the first NMOS transistor and having a gate receiving a second voltage, the second NMOS transistor being longer than the first NMOS transistor.

In accordance with another aspect of the present invention, there is provided a flip-flop circuit including: a plurality of unit flip-flops each having an inverter latch; a pull-up transistor for supplying a pull-up voltage to the unit flip-flops; and a pull-down transistor for supplying a pull-down voltage to the unit flip-flops, wherein a channel length of the pull-up transistor is longer than that of an inverter of the inverter latch.

In accordance with a further aspect of the present invention, there is provided an inverter latch including: a first inverter for inverting a signal of a first node and transferring an inverted signal to a second node; and a second inverter for feeding back a signal of the second node and transferring a feedback signal to the first node, wherein the second inverter includes: a first PMOS transistor and a first NMOS transistor, each gate of which receives the signal of the second node; a second PMOS transistor connected to the first PMOS transistor and having a gate receiving a first voltage, the second PMOS transistor being longer than the first PMOS transistor; and a second NMOS transistor connected to the first NMOS transistor and having a gate receiving a second voltage, the second NMOS transistor being longer than the first NMOS transistor.

### BRIEF DESCRIPTION OF THE DRAWINGS

The above and other objects and features of the present invention will become apparent from the following description of the preferred embodiments given in conjunction with the accompanying drawings, in which:

FIG. 1 is a circuit diagram of a conventional D flip-flop circuit;

FIG. 2 is a timing diagram of the D flip-flop circuit illustrated in FIG. 1;

FIG. 3 is a circuit diagram of a first inverter and a second inverter illustrated in FIG. 1;

FIG. 4 is a circuit diagram of a first inverter and a second inverter in accordance with a first embodiment of the present invention;

FIG. 5 is a block diagram of a D flip-flop circuit having the inverters of FIG. 4 in accordance with a second embodiment of the present invention;

FIG. 6A is a circuit diagram of a unit D flip-flop circuit illustrated in FIG. 5;

FIG. 6B is a circuit diagram of a feedback inverter in the unit D flip-flop circuit of FIG. 6A;

FIG. 6C is a circuit diagram of a pull-up driver of FIG. 5; and

FIG. 6D is a circuit diagram of a pull-down driver of FIG. 5.

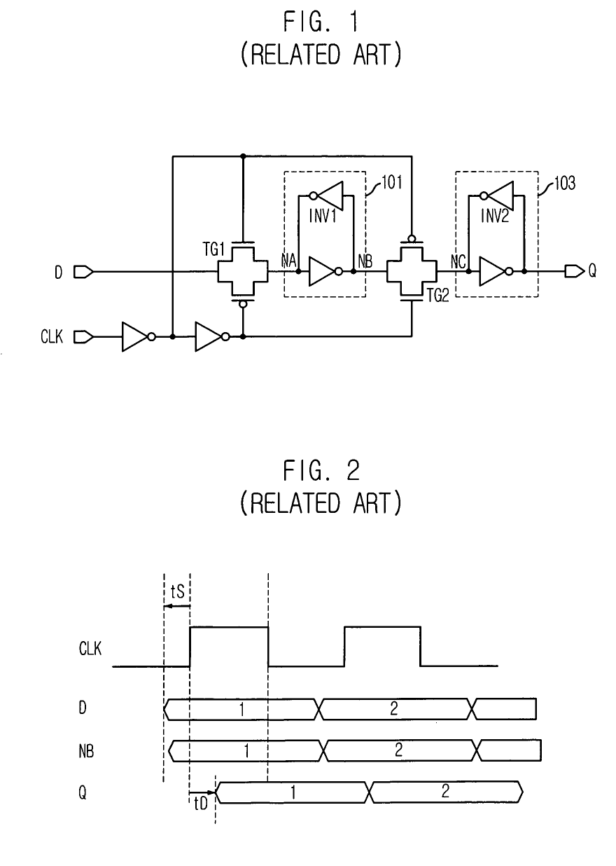

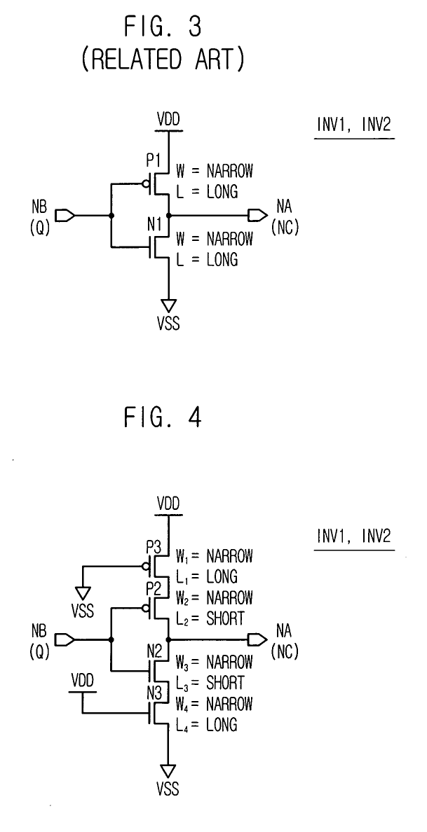

### DETAILED DESCRIPTION OF THE INVENTION

A flip-flop circuit of a semiconductor memory device in accordance with exemplary embodiments of the present invention will be described in detail with reference to the accompanying drawings.

FIG. 4 is a circuit diagram of a first inverter and a second inverter of a D flip-flop circuit in accordance with a first embodiment of the present invention.

The first inverter INVL includes a first PMOS transistor P2, a first NMOS transistor N2, a second PMOS transistor P3, and a second NMOS transistor N3. The first PMOS transistor P2 and the first NMOS transistor N2 have gates receiving a first signal NB to output a second signal NA. The second PMOS transistor P3 has a gate receiving a ground voltage VSS and is connected between the first PMOS transistor P2 and a power supply voltage VDD. The second NMOS transistor N3 is connected between the first NMOS transistor N2 and the ground voltage VSS and has a gate receiving the power supply voltage VDD. The second inverter INV2 has the same structure as the first inverter INV1, except that the first PMOS transistor P2 and the first NMOS transistor N2 have gates receiving a first signal Q to output a second signal NC.

The second PMOS transistor P3 and the second NMOS transistor N3 are formed to have narrow width W₁ and W₄ and long lengths L₁ and L₄. The first PMOS transistor P2 and the first NMOS transistor N2 are formed to have narrow widths W₂ and W₃ and short lengths L₂ and L₃.

The problem of the conflict between the transmission signal and the feedback signal of the latch can be solved by the second PMOS transistor P3 and the second NMOS transistor N3 having narrow width W₁ and W₄ and long lengths L₁ and L₄. In addition, the problem that increases the load at the nodes NA and NB can be solved by the first PMOS transistor P2 and the first NMOS transistor N2 having narrow widths W₂ and W₃ and short lengths L₂ and L₃.

If such flip-flop circuits having the improved operation characteristic are provided in plurality, they will occupy a large area. To solve this problem, the flip-flop circuit is implemented as follows.

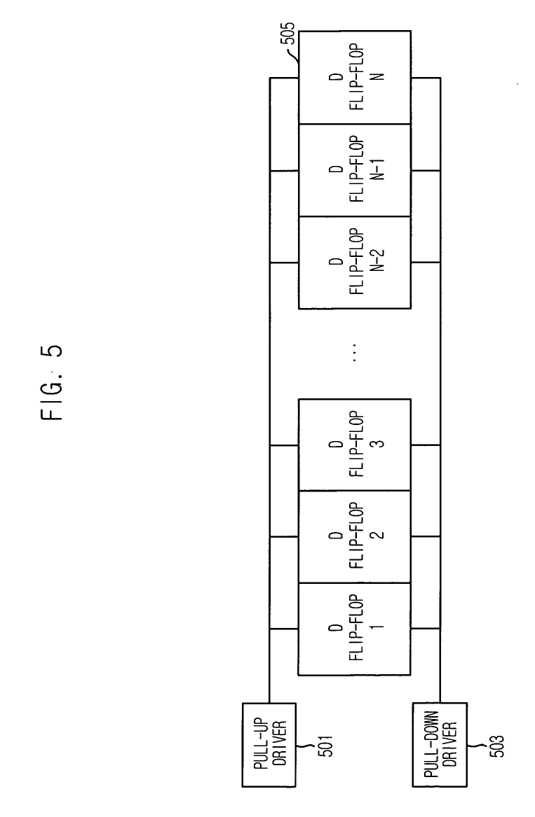

FIG. 5 is a block diagram of a D flip-flop circuit having the inverters of FIG. 4 in accordance with a second embodiment of the present invention.

The D flip-flop circuit includes N numbers of unit D flip-flops 505, a pull-up driver 501, and a pull-down driver 503. The pull-up driver 501 and the pull-down driver 503 are connected to the unit D flip-flops.

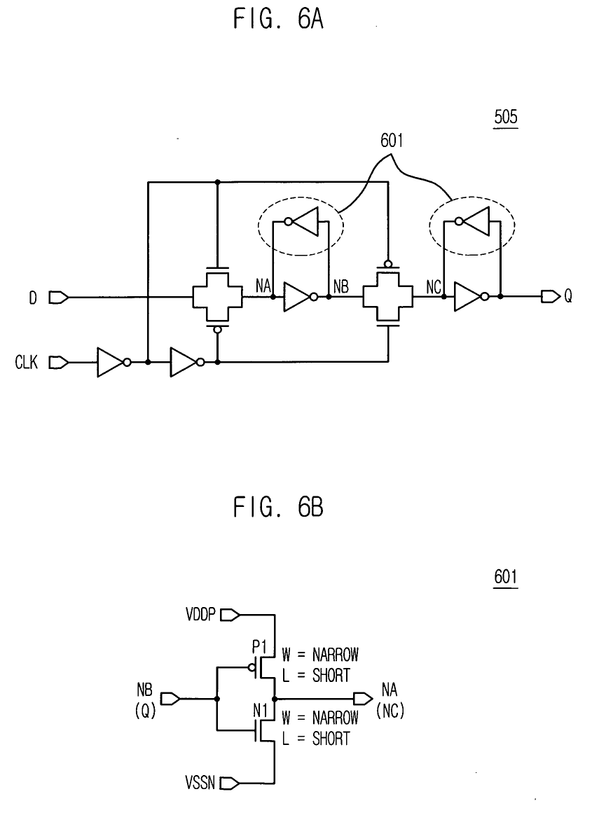

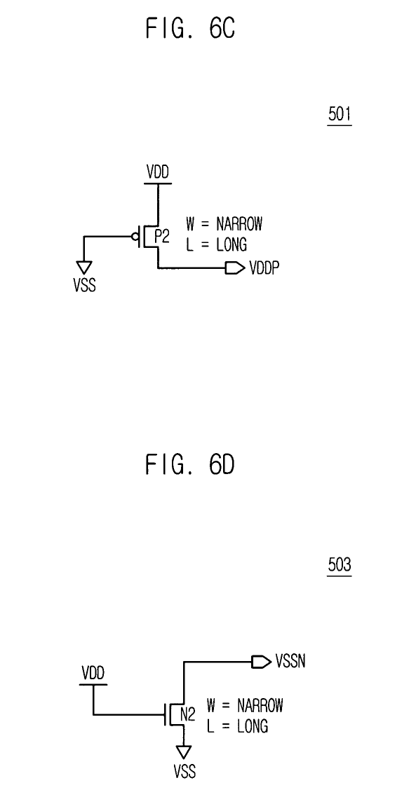

FIG. 6A is a circuit diagram of the unit D flip-flop 505 illustrated in FIG. 5. Since the unit D flip-flop 505 of FIG. 6A is substantially the same as that of FIG. 1, a detailed description thereof will be omitted.

FIG. 6B is a circuit diagram of a feedback inverter 601 of the unit D flip-flop 505 illustrated in FIG. 6A.

The feedback inverter 601 includes a first PMOS transistor P4 and a first NMOS transistor N4. The first PMOS transistor P4 and the first NMOS transistor N4 have gates receiving a first signal NB (Q) and outputs a second signal NA (NC). The first PMOS transistor P4 is connected to an output signal VDDP of the pull-up driver 501. The first NMOS transistor N4 is connected to an output signal VSSP of the pull-down driver 503.

The first PMOS transistor P4 and the first NMOS transistor N4 are formed to have narrow widths and short lengths.

FIGS. 6C and 6D are circuit diagrams of the pull-up driver 501 and the pull-down driver 503 illustrated in FIG. 5, respectively.

Referring to FIG. 6C, the pull-up driver 501 includes a second PMOS transistor P5 having a gate receiving the ground voltage VSS and connected between the output signal VDDP and the power supply voltage VDD.

Referring to FIG. 6D, the pull-down driver 503 includes a second NMOS transistor N5 having a gate receiving the power supply voltage VDD and connected between the output signal VSSN and the ground voltage VSS.

The second PMOS transistor P5 and the second NMOS transistor N5 are formed to have narrow widths and long lengths.

The problem of the fight between the transmission signal and the feedback signal of the latch can be solved by the second PMOS transistor P5 and the second NMOS transistor N5 of the pull-up driver 501 and the pull-down driver 503. In addition, the problem that increases the load at the nodes NA and NB can be solved by the first PMOS transistor P4 and the first NMOS transistor N4 having narrow widths and short lengths.

The problem that increases the size of the semiconductor device in forming a plurality of D flip-flops can be solved by sharing the pull-up driver 501 and the pull-down driver 503. Moreover, the second PMOS transistor P5 of the pull-up driver 501 and the second NMOS transistor N5 of the pull-down driver 503 may be replaced with a passive element such as a resistor.

As described above, the present invention can increase signal transfer capability of the inverter feeding back its own output signal and can reduce the load between both nodes of the inverter, thereby improving transfer characteristic of the latch input signal.

Therefore, the present invention can improve the operation characteristic of the semiconductor memory device having the latches.

In the aforementioned embodiments, the kinds and arrangements of the logics have been provided for the case where the input signals and output signals are all high active signals. Therefore, when the active polarities of the signals are changed, the logic implementations will be also modified. The number of cases for these implementations is extensive and their modifications can be easily derived by those skilled in the art.

The present application contains subject matter related to Korean patent application Nos. 2005-90905 & 2006-38715, filed in the Korean Intellectual Property Office on Sep. 29, 2005 & Apr. 28, 2006, the entire contents of which is incorporated herein by reference.

While the present invention has been described with respect to certain preferred embodiments, it will be apparent to those skilled in the art that various changes and modifications may be made without departing from the scope of the invention as defined in the following claims.

What is claimed is:

1. A flip-flop circuit, comprising:
a first inverter for inverting a signal of a first node and transferring an inverted signal to a second node; and
a second inverter for feeding back a signal of the second node and transferring a feedback signal to the first node,
wherein the second inverter includes:
a first PMOS transistor and a first NMOS transistor, each gate of which receives the signal of the second node;
a second PMOS transistor connected to the first PMOS transistor and having a gate receiving a first voltage, the second PMOS transistor being longer than the first PMOS transistor; and
a second NMOS transistor connected to the first NMOS transistor and having a gate receiving a second voltage, the second NMOS transistor being longer than the first NMOS transistor.

2. The flip-flop circuit of claim 1, wherein the first voltage is a ground voltage and the second voltage is a power supply voltage.

3. A flip-flop circuit, comprising:
a plurality of unit flip-flops each having an inverter latch;
a pull-up transistor for supplying a pull-up voltage to the unit flip-flops; and
a pull-down transistor for supplying a pull-down voltage to the unit flip-flops,
wherein a channel length of the pull-up transistor is longer than that of an inverter of the inverter latch.

4. The flip-flop circuit of claim 3, wherein the inverter feeds back a signal from an output node to an input node of the inverter latch.

5. The flip-flop circuit of claim 4, wherein the inverter includes:
a first PMOS transistor and a first NMOS transistor, each gate of which receives the signal of the output node;
a second PMOS transistor connected to the first PMOS transistor and having a gate receiving a first voltage, the second PMOS transistor being longer than the first PMOS transistor; and
a second NMOS transistor connected to the first NMOS transistor and having a gate receiving a second voltage, the second NMOS transistor being longer than the first NMOS transistor.

6. The flip-flop circuit of claim 5, wherein the first voltage is a ground voltage and the second voltage is a power supply voltage.

7. An inverter latch, comprising:
a first inverter for inverting a signal of a first node and transferring an inverted signal to a second node; and
a second inverter for feeding back a signal of the second node and transferring a feedback signal to the first node,
wherein the second inverter includes:
a first PMOS transistor and a first NMOS transistor, each gate of which receives the signal of the second node;
a second PMOS transistor connected to the first PMOS transistor and having a gate receiving a first voltage, the second PMOS transistor being longer than the first PMOS transistor; and
a second NMOS transistor connected to the first NMOS transistor and having a gate receiving a second voltage, the second NMOS transistor being longer than the first NMOS transistor.

8. The inverter latch of claim 7, wherein the first voltage is a ground voltage and the second voltage is a power supply voltage.
